(19) United States
(12) Patent Application Publication
(10) Pub. No.: US 2023/0318211 A1
(43) Pub. Date: Oct. 5, 2023

(54) Liquid-Proof Edge Connector Designs for Immersion Cooling

(71) Applicant: Intel Corporation, Santa Clara, CA (US)

(72) Inventors: Xiang Li, Portland, OR (US); Shaohua Li, Pleasanton, CA (US); Jingbo Li, Portland, OR (US); Mo Liu, Santa Clara, CA (US); Kai Xiao, Portland, OR (US); Kai Wang, Portland, OR (US)

(73) Assignee: Intel Corporation, Santa Clara, CA (US)

(21) Appl. No.: 18/130,404

(22) Filed: Apr. 3, 2023

(51) Int. Cl. H01R 12/72; H01R 13/52; H01R 4/02

(52) U.S. Cl. CPC H01R 12/721; H01R 13/5219; H01R 13/5216; H01R 4/023; H05K 7/20236

(57) ABSTRACT

Methods and apparatus relating to liquid-proof edge connector solutions for immersion cooling are described. In one embodiment, a seal prevents a cooling liquid to cause electrical contact with a pin of an edge card to be inserted in a connector. And, an adhesive prevents the cooling liquid to cause electrical contact with a terminal of the connector. Other embodiments are also claimed and disclosed.

### FIELD OF THE INVENTION

The present disclosure generally relates to the field of electronics. More particularly, an embodiment relates to a liquid-proof edge connector design for immersion cooling.

### BACKGROUND OF THE INVENTION

With the increasing power consumption of data center, immersion cooling solution is gaining popularity with Cloud Service Providers (CSPs) to improve cooling efficiency. Immersion cooling solution may also provide a key technology for sustainable data center solutions. However, electrical performance of high-speed components immersed in a liquid with higher dielectric constant (or “Dk”) can be quite different from that in the air (e.g., Dk=¹⁸ 1.8-2.3 in liquid vs. Dk=1 in air).

### BRIEF DESCRIPTION OF DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1A illustrates a side view diagram of a cable topology in an immersion liquid, according to an embodiment.

FIG. 1B illustrates a plot of a cable topology, according to one embodiment.

FIGS. 2A, 2B, 2C, and 2D illustrate simulated eye height and eye width of the cable topology, according to some embodiments.

FIG. 3 illustrates perspective and side views of a connector, according to some embodiments.

FIG. 4 illustrates a block diagram of an embodiment of a computing system, which may be utilized in various embodiments discussed herein.

FIG. 5 illustrates a block diagram of an embodiment of a computing system, which may be utilized in various embodiments discussed herein.

FIG. 6 illustrates various components of a processer in accordance with some embodiments.

### DETAILED DESCRIPTION OF THE INVENTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware (such as logic circuitry or more generally circuitry or circuit), software, firmware, or some combination thereof.

As mentioned above, with the increasing power consumption of data center, immersion cooling solution is gaining popularity with Cloud Service Providers (CSPs) to improve cooling efficiency. Immersion cooling solution may also provide a key technology for sustainable data center solutions. However, electrical performance of high-speed components immersed in a liquid with higher dielectric constant (or “Dk” which is sometimes interchangeably referred to herein as “Er”) can be quite different from that in air (e.g., with a liquid Dk of approximately 1.8 to 2.3 versus an air Dk of 1).

To this end, some embodiments relate to provision of liquid-proof edge connectors for immersion cooling. In an embodiment, a solution to reduce the impact on electrical performance from immersion cooling is provided for a different Dk of an immersion liquid. Sealing the connector may maintain the electrical performance of the connector before and after immersion in a cooling liquid (such as fluorochemical liquids, polyalphaolefin, mineral oil, etc.). With such a sealing approach, performance of the connector would not be impacted by variation of Dk of different liquids in one or more embodiments.

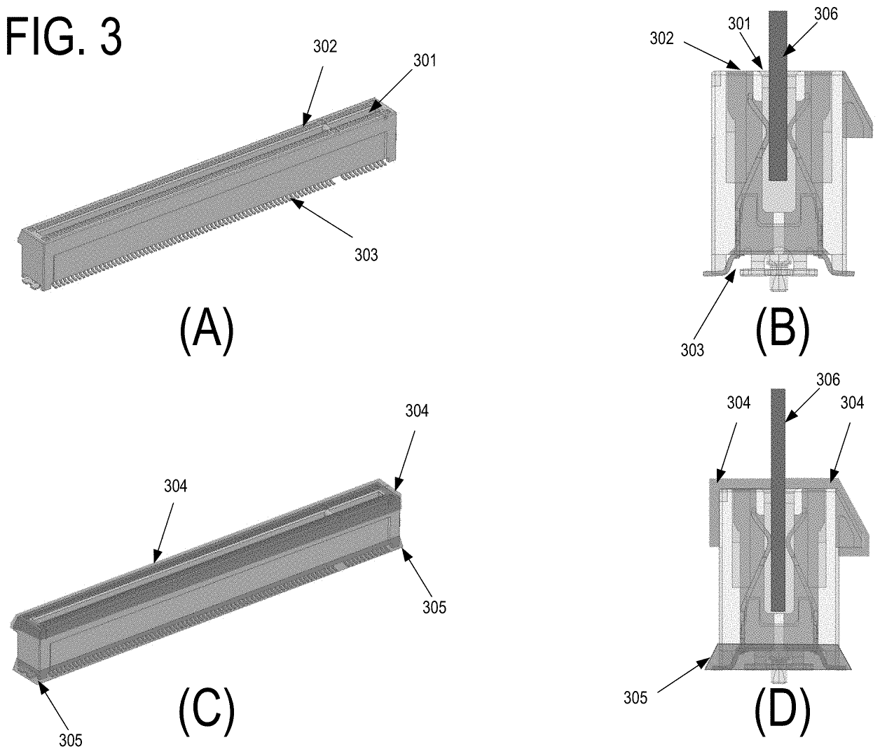

In one embodiment, a connector is sealed at the gap between the connector receptacle and plug board, as well as the connection between the connector receptacle and the Printed Circuit Board (PCB) as further discussed with reference to FIG. 3, by an adhesive, such as one or more of: silicone (such as Polyalkylsiloxane, Polydimethyl-siloxane, etc.), hot glue (or another glue, e.g., activated by ultraviolet light), epoxy, polymer composite, glass solder, rubber, natural rubber, Styrene butadiene rubber, Butadine rubber (or Polybutadine CIS-1, 4 (>97%)), Isoprene rubber, Ethylene-Propylene-Diene-Monomer (“EPDM” or Polyethylene-co-propylene-co-diene), Butyl rubber, Nitrile rubber, Chloroprene rubber, Fluorocarbon elastomers, Plysulfide rubber, Polyurethanes, Hypalon™ (or Chlorosulfonated polyethylene), etc.) is applied to the connection part between the connector and a circuit board after the connector is attached (e.g., by soldering) to the circuit board.

For example, in various embodiments (e.g., based on simulation and/or measurement), it can be observed that an eye margin degradation may mainly originate from the components, such as connectors, that are immersed in liquid. Moreover, an immersed connector may perform differently with a different Dk of the liquid. Further, it is expected that the performance of a channel at higher signaling speed and pulse amplitude modulation 4-level (PAM-4) mode, such as a Peripheral Component Interconnect express revision 6.0 (PCIe 6.0 or “PCIe Gen6”) channel would be more sensitive to reflection noise than a channel at lower speed and non-return zero (NRZ) coding mode, such as PCIe revision 5.0 (or PCIe Gen5).

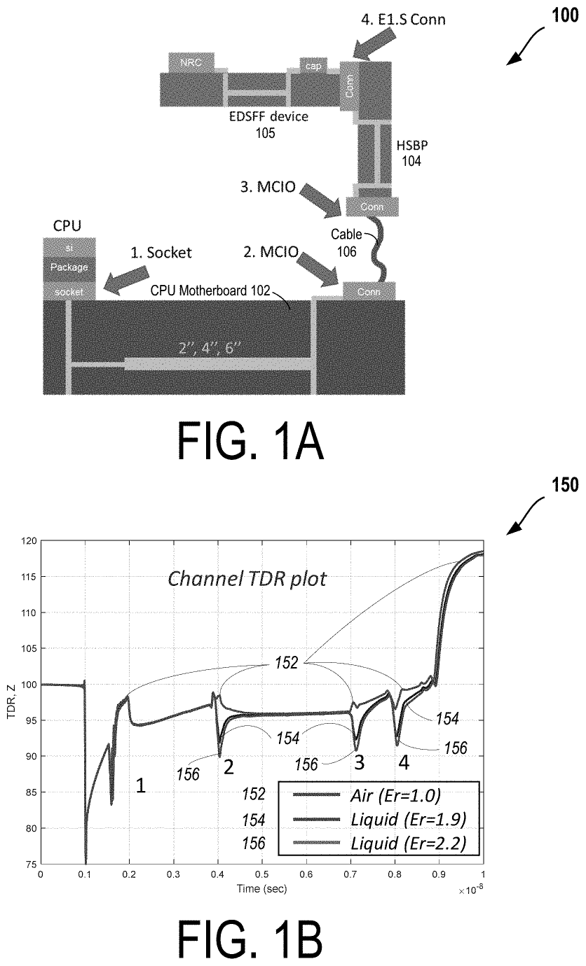

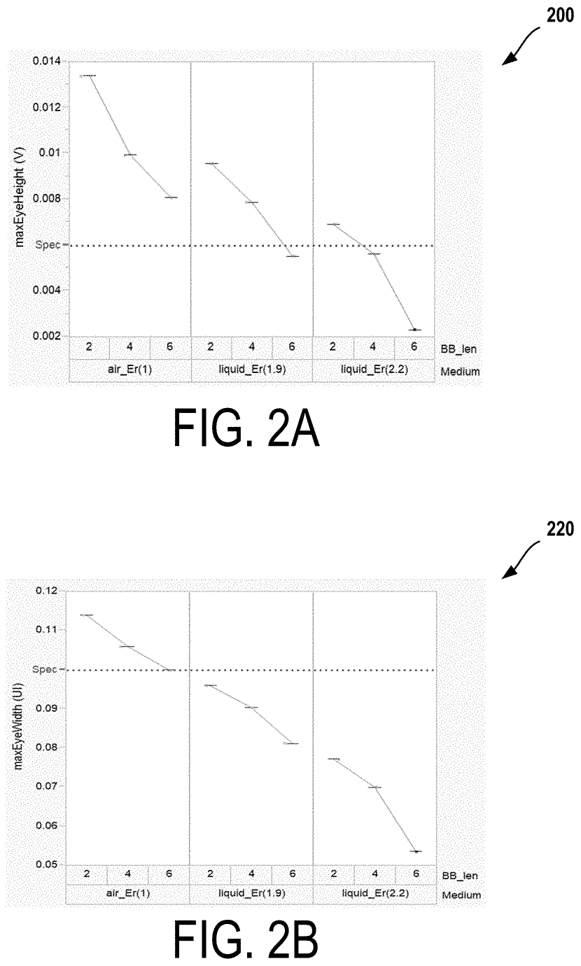

FIG. 1A illustrates a side view diagram of a Mini Cooledge Input Output (MCIO) cable topology of PCIe Gen6 and PCIe Gen5 evaluated in an immersion liquid, according to an embodiment. FIG. 1B illustrates a Time Domain Reflectometry (TDR) plot of a MCIO cable topology (e.g., such as shown in FIG. 1A) in different cooling conditions, according to one embodiment.

Generally, immersion cooling can provide stable ambient temperature for computing systems, and consequently provide a stable system performance. For example, FIG. 1A shows an example of a PCIe channel topology 100 which may be used on a data center platform with PCIe Gen5 and/or Gen6 interface. A Central Processing Unit (CPU) motherboard 102 is coupled to external devices through exchangeable modules like Hot Swap Back Plane (HSBP) 104, an end device (such as an Enterprise and Data Center Standard Form Factor (EDSFF) device 105 coupled via the HSBP 104), and cable(s) 106. The E1.S connector 108 provides a form factor to deliver data center-optimized storage in at least one embodiment.

In FIG. 1A, “NRC” refers to non-root complex, and one or more embodiments, it refers to an endpoint, such as an EDSFF device, CEM (or Card Electromechanical specification) card, etc. In PCIe implementations, there is generally a root complex (which typically resides in a CPU) which serves as the host to a plurality of non-root-complex endpoints.

Referring to FIG. 1B, the TDR performance of the receive (Rx) link topology of FIG. 1A is shown. The TDR plot 150 includes markings 2-4 respectively corresponding to locations 2-4 of FIG. 1A (i.e., MCIO at CPU motherboard connector, MCIO at HSBO connector, and E1.S connector). Generally, most or all large impedance drops occur at the interconnect having the contact in the immersion liquid. The connector impedance is different in the liquid, e.g., with Dk=1.9 and Dk=2.2 (where the air and the liquid dielectric constants are labeled as 152, 154, and 156 in FIG. 1B). More particularly, contact in the immersion liquid generally refers to contact at the interconnect having the direct contact or electrical field distributed in the immersion liquid. Also, an impedance drop may occur when there are the electrical field lines distributing in the liquid, which may be present when: (1) the metal structures are directly exposed, such as a connector pin; and (2) the metal is surrounded with some dielectric material, but the dielectric material is too thin to contain all the electrical field, such as a micro-strip with a thin layer of solder mask.

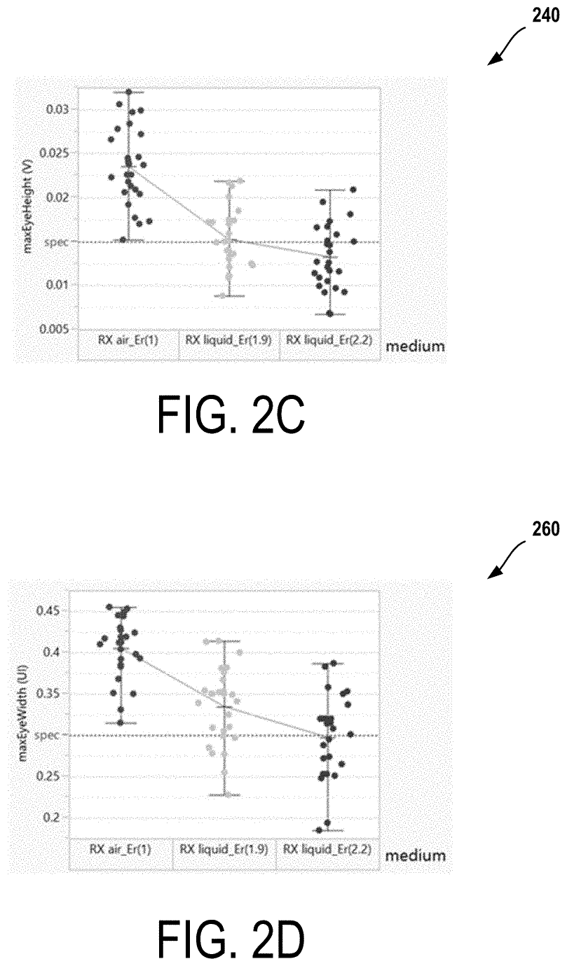

FIGS. 2A and 2B illustrate simulated eye height and eye width of the cable topology of FIG. 1A in different immersion liquids at PCIe Gen6 speed with specification receiver, according to some embodiments. Moreover, Eye Height (EH) and Eye Width (EW) drop from air to the liquid, e.g., Dk=1.9 and the liquid Dk=2.2 is about 22%/11% and 42%/31% for four inch motherboards, respectively. Without any change of the current connector design, no solution space is found for this cable topology in immersion cooling.

In PCIe Gen5 speed, the impact of immersion liquid with different Dk on the eye margin can also be seen in FIGS. 2C and 2D, according to some embodiments. More particularly, FIGS. 2C and 2D illustrate the simulated EH and EW of the MCIO topology at PCIe Gen5 with total Printed Circuit Board (PCB) length of nine inch in different cooling conditions (240 and 260, respectively), according to some embodiments. EH/EW drop from air to the liquid Dk=1.9 and Dk=2.2 is 36%/15% and 35%/21%, respectively. With different cooling liquid, eye margin varies. Hence, the topology of FIG. 1A with total PCB length of nine inch at PCIe Gen5 has 36%/15% and 35%/21% EH/EW drop from air to the liquid Dk=1.9 and the liquid Dk=2.2, respectively. Further, although a new connector may be designed for immersion cooling applications to avoid the big eye drop from air to the liquid, it can still be a challenge to select the liquid Dk for connector target impedance. Besides impedance variation from manufacture, liquid Dk may add an extra three percent of impedance variation.

Hence, at least one embodiment reduces the performance impact from different immersion liquids. In an embodiment, the connector is sealed at the gap between the connector receptacle and plug board and adhesive is applied to the connection part between the connector and circuit board after the connector is soldered on the board.

FIG. 3 illustrates perspective and side views of a connector, according to some embodiments. More particularly, FIGS. 3 (A) and 3 (B) show three paths (301 (the gap between the connector slot and the add-in card 306), 302 (the aperture of each pin), and 303 (the exposed Surface-Mount Technology (SMT) terminal and gap between connector housing and the PCB board)) of the liquid filling into a connector. FIGS. 3 (C) and 3 (D) illustrate the perspective view and side view after the connector is sealed, according to some embodiments. It is expected that with a liquid-proof connector, the connector may be used in any immersion cooling liquid, which would provide customers more flexibility to choose the immersion cooling liquid. In one embodiment, with the sealing connector design, the connector can be used in immersion cooling on PCIe Gen5 without other changes. From PCIe Gen6 simulation with specification receiver, no solution space is found for a three-connector cable topology when the connector designed for air is directly used in immersion cooling. From PCIe Gen5 simulation with specification receiver, the three-connector topology (such as shown in FIG. 1A) has approximately 30% eye height degradation when the connector is used in immersion cooling. The connector designed for air cooling may be changed to be used in immersion cooling.

Referring to FIGS. 3C and 3D, a silicone gel provides a seal 304 (e.g., provided in the form of a silicone gasket) to cover the connector top surface and/or seal the aperture of each pin to avoid liquid infiltration. While silicone is used in one embodiment, other liquid-impermeable material may be used for the seal 304, such as those discussed above with reference to adhesive. As shown, the bottom part of the connector to the PCB surface may be covered by an adhesive 305 (such as those discussed above, including, for example, hot glue) in at least one embodiment. Adhesive 305 may cover the exposed terminal(s) and seal the gap between the connector housing and the motherboard.

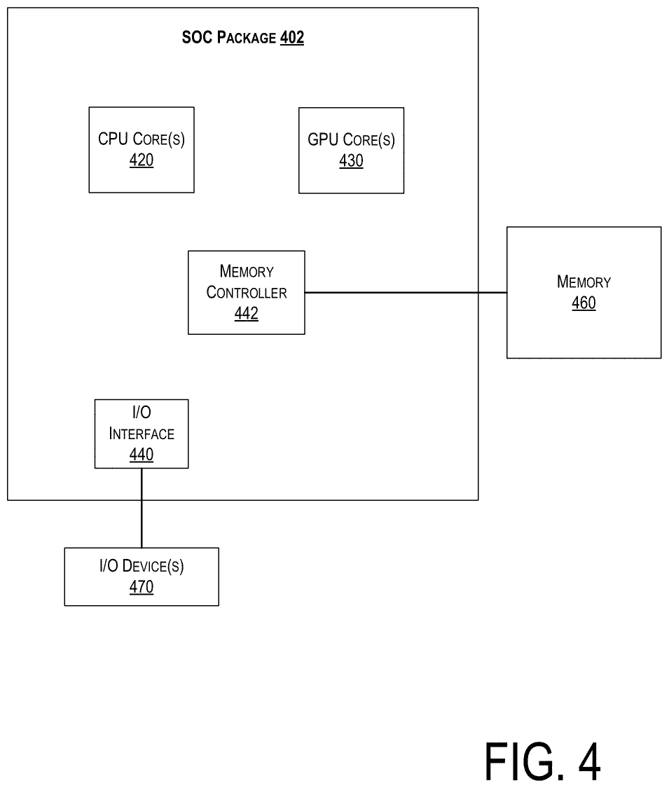

One or more components discussed with reference to FIGS. 4-6 (including but not limited to I/O devices, memory/storage devices, graphics/processing cards/devices, network/bus/audio/display/graphics controllers, wireless transceivers, etc.) may be protected/sealed for liquid immersion utilizing the techniques discussed above with reference to FIGS. 1A-3. More particularly, FIG. 4 illustrates a block diagram of a System on Chip (“SOC” or “SoC”) package in accordance with an embodiment. As illustrated in FIG. 4, SOC 402 includes one or more Central Processing Unit (CPU) or processor cores 420, one or more Graphics Processor Unit (GPU) cores 430, an Input/Output (I/O) interface 440, and a memory controller 442. Various components of the SOC package 402 may be coupled to an interconnect or bus such as discussed herein with reference to the other figures. Also, the SOC package 402 may include more or less components, such as those discussed herein with reference to the other figures. Further, each component of the SOC package 420 may include one or more other components, e.g., as discussed with reference to the other figures herein. In one embodiment, SOC package 402 (and its components) is provided on one or more Integrated Circuit (IC) die, e.g., which are packaged into a single semiconductor device.

As illustrated in FIG. 4, SOC package 402 is coupled to a memory 460 via the memory controller 442. In an embodiment, the memory 460 (or a portion of it) can be integrated on the SOC package 402.

The I/O interface 440 may be coupled to one or more I/O devices 470, e.g., via an interconnect and/or bus such as discussed herein with reference to other figures. I/O device(s) 470 may include one or more of a keyboard, a mouse, a touchpad, a display, an image/video capture device (such as a camera or camcorder/video recorder), a touch screen, a speaker, or the like.

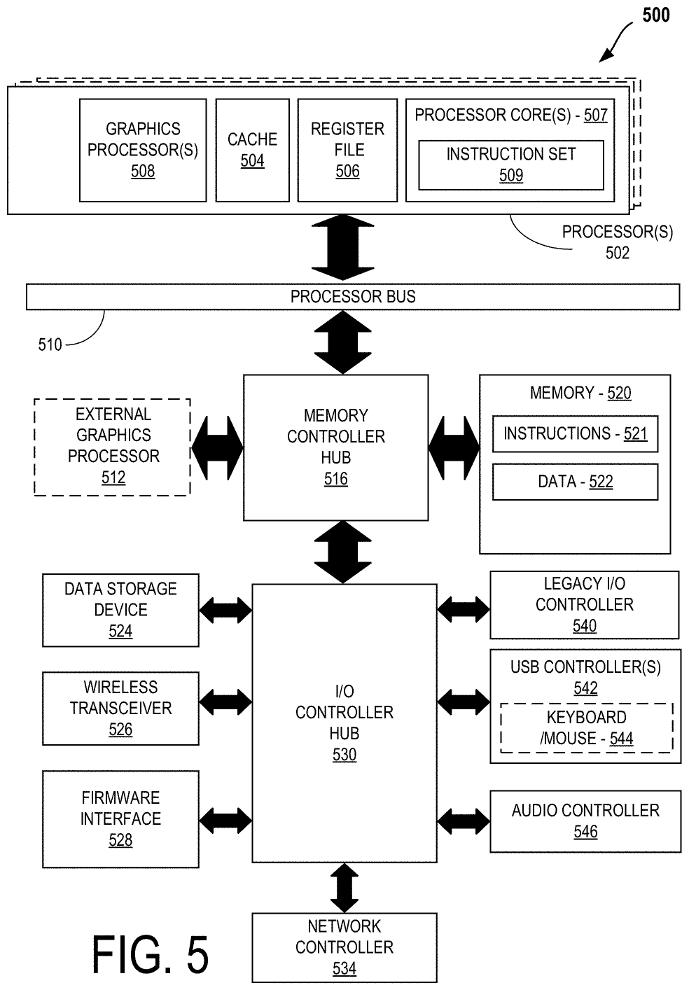

FIG. 5 is a block diagram of a processing system 500, according to an embodiment. In various embodiments the system 500 includes one or more processors 502 and one or more graphics processors 508, and may be a single processor desktop system, a multiprocessor workstation system, or a server system having a large number of processors 502 or processor cores 507. In an embodiment, the system 500 is a processing platform incorporated within a system-on-a-chip (SoC or SOC) integrated circuit for use in mobile, handheld, or embedded devices.

An embodiment of system 500 can include, or be incorporated within a server-based gaming platform, a game console, including a game and media console, a mobile gaming console, a handheld game console, or an online game console. In some embodiments system 500 is a mobile phone, smart phone, tablet computing device or mobile Internet device. Data processing system 500 can also include, couple with, or be integrated within a wearable device, such as a smart watch wearable device, smart eyewear device, augmented reality device, or virtual reality device. In some embodiments, data processing system 500 is a television or set top box device having one or more processors 502 and a graphical interface generated by one or more graphics processors 508.

In some embodiments, the one or more processors 502 each include one or more processor cores 507 to process instructions which, when executed, perform operations for system and user software. In some embodiments, each of the one or more processor cores 507 is configured to process a specific instruction set 509. In some embodiments, instruction set 509 may facilitate Complex Instruction Set Computing (CISC), Reduced Instruction Set Computing (RISC), or computing via a Very Long Instruction Word (VLIW). Multiple processor cores 507 may each process a different instruction set 509, which may include instructions to facilitate the emulation of other instruction sets. Processor core 507 may also include other processing devices, such a Digital Signal Processor (DSP).

In some embodiments, the processor 502 includes cache memory 504. Depending on the architecture, the processor 502 can have a single internal cache or multiple levels of internal cache. In some embodiments, the cache memory is shared among various components of the processor 502. In some embodiments, the processor 502 also uses an external cache (e.g., a Level-3 (L3) cache or Last Level Cache (LLC)) (not shown), which may be shared among processor cores 507 using known cache coherency techniques. A register file 506 is additionally included in processor 502 which may include different types of registers for storing different types of data (e.g., integer registers, floating point registers, status registers, and an instruction pointer register). Some registers may be general-purpose registers, while other registers may be specific to the design of the processor 502.

In some embodiments, processor 502 is coupled to a processor bus 510 to transmit communication signals such as address, data, or control signals between processor 502 and other components in system 500. In one embodiment the system 500 uses an exemplary ‘hub’ system architecture, including a memory controller hub 516 and an Input Output (I/O) controller hub 530. A memory controller hub 516 facilitates communication between a memory device and other components of system 500, while an I/O Controller Hub (ICH) 530 provides connections to I/O devices via a local I/O bus. In one embodiment, the logic of the memory controller hub 516 is integrated within the processor.

Memory device 520 can be a dynamic random access memory (DRAM) device, a static random access memory (SRAM) device, flash memory device, phase-change memory device, or some other memory device having suitable performance to serve as process memory. In one embodiment the memory device 520 can operate as system memory for the system 500, to store data 522 and instructions 521 for use when the one or more processors 502 executes an application or process. Memory controller hub 516 also couples with an optional external graphics processor 512, which may communicate with the one or more graphics processors 508 in processors 502 to perform graphics and media operations.

In some embodiments, ICH 530 enables peripherals to connect to memory device 520 and processor 502 via a high-speed I/O bus. The I/O peripherals include, but are not limited to, an audio controller 546, a firmware interface 528, a wireless transceiver 526 (e.g., Wi-Fi, Bluetooth), a data storage device 524 (e.g., hard disk drive, flash memory, etc.), and a legacy I/O controller 540 for coupling legacy (e.g., Personal System 2 (PS/2)) devices to the system. One or more Universal Serial Bus (USB) controllers 542 connect input devices, such as keyboard and mouse 544 combinations. A network controller 534 may also couple to ICH 530. In some embodiments, a high-performance network controller (not shown) couples to processor bus 510. It will be appreciated that the system 500 shown is exemplary and not limiting, as other types of data processing systems that are differently configured may also be used. For example, the I/O controller hub 530 may be integrated within the one or more processor 502, or the memory controller hub 516 and I/O controller hub 530 may be integrated into a discreet external graphics processor, such as the external graphics processor 512.

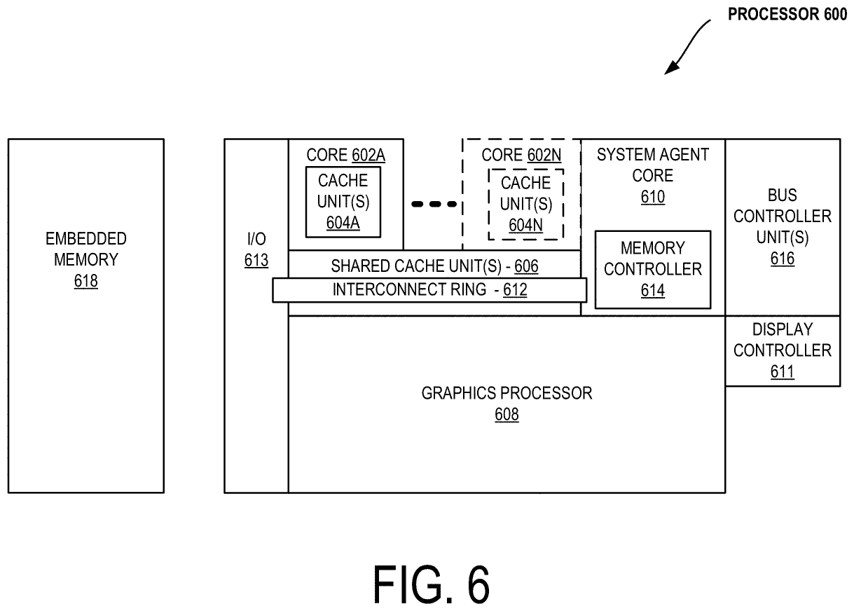

FIG. 6 is a block diagram of an embodiment of a processor 600 having one or more processor cores 602A to 602N, an integrated memory controller 614, and an integrated graphics processor 608. Those elements of FIG. 6 having the same reference numbers (or names) as the elements of any other figure herein can operate or function in any manner similar to that described elsewhere herein, but are not limited to such. Processor 600 can include additional cores up to and including additional core 602N represented by the dashed lined boxes. Each of processor cores 602A to 602N includes one or more internal cache units 604A to 604N. In some embodiments each processor core also has access to one or more shared cached units 606.

The internal cache units 604A to 604N and shared cache units 606 represent a cache memory hierarchy within the processor 600. The cache memory hierarchy may include at least one level of instruction and data cache within each processor core and one or more levels of shared mid-level cache, such as a Level 2 (L2), Level 3 (L3), Level 4 (L4), or other levels of cache, where the highest level of cache before external memory is classified as the LLC. In some embodiments, cache coherency logic maintains coherency between the various cache units 606 and 604A to 604N.

In some embodiments, processor 600 may also include a set of one or more bus controller units 616 and a system agent core 610. The one or more bus controller units 616 manage a set of peripheral buses, such as one or more Peripheral Component Interconnect buses (e.g., PCI, PCI Express). System agent core 610 provides management functionality for the various processor components. In some embodiments, system agent core 610 includes one or more integrated memory controllers 614 to manage access to various external memory devices (not shown).

In some embodiments, one or more of the processor cores 602A to 602N include support for simultaneous multi-threading. In such embodiment, the system agent core 610 includes components for coordinating and operating cores 602A to 602N during multi-threaded processing. System agent core 610 may additionally include a power control unit (PCU), which includes logic and components to regulate the power state of processor cores 602A to 602N and graphics processor 608.

In some embodiments, processor 600 additionally includes graphics processor 608 to execute graphics processing operations. In some embodiments, the graphics processor 608 couples with the set of shared cache units 606, and the system agent core 610, including the one or more integrated memory controllers 614. In some embodiments, a display controller 611 is coupled with the graphics processor 608 to drive graphics processor output to one or more coupled displays. In some embodiments, display controller 611 may be a separate module coupled with the graphics processor via at least one interconnect, or may be integrated within the graphics processor 608 or system agent core 610.

In some embodiments, a ring-based interconnect unit 612 is used to couple the internal components of the processor 600. However, an alternative interconnect unit may be used, such as a point-to-point interconnect, a switched interconnect, or other techniques, including techniques well known in the art. In some embodiments, graphics processor 608 couples with the ring interconnect 612 via an I/O link 613.

The exemplary I/O link 613 represents at least one of multiple varieties of I/O interconnects, including an on package I/O interconnect which facilitates communication between various processor components and a high-performance embedded memory module 618, such as an eDRAM (or embedded DRAM) module. In some embodiments, each of the processor cores 602 to 602N and graphics processor 608 use embedded memory modules 618 as a shared Last Level Cache.

In some embodiments, processor cores 602A to 602N are homogenous cores executing the same instruction set architecture. In another embodiment, processor cores 602A to 602N are heterogeneous in terms of instruction set architecture (ISA), where one or more of processor cores 602A to 602N execute a first instruction set, while at least one of the other cores executes a subset of the first instruction set or a different instruction set. In one embodiment processor cores 602A to 602N are heterogeneous in terms of microarchitecture, where one or more cores having a relatively higher power consumption couple with one or more power cores having a lower power consumption. Additionally, processor 600 can be implemented on one or more chips or as an SoC integrated circuit having the illustrated components, in addition to other components.

The following examples pertain to further embodiments. Example 1 includes an apparatus comprising: a seal to prevent a cooling liquid from making electrical contact with a pin of an edge card to be inserted in a connector; and an adhesive to prevent the cooling liquid to cause electrical contact with a terminal of the connector, wherein the connector is to be coupled to a printed circuit board prior to application of the adhesive. Example 2 includes the apparatus of example 1, wherein the connector is to be coupled to the printed circuit board via soldering. Example 3 includes the apparatus of example 1, wherein the cooling liquid comprises a fluorochemical liquid, a polyalphaolefin liquid, mineral oil, or combinations thereof.

Example 4 includes the apparatus of example 1, wherein the seal comprises silicone gel. Example 5 includes the apparatus of example 1, wherein the adhesive comprises hot glue. Example 6 includes the apparatus of example 1, wherein the seal comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene. Example 7 includes the apparatus of example 1, wherein the adhesive comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene. Example 8 includes the apparatus of example 1, wherein the edge card comprises one or more of: a processor, a storage device, a communication device, or an input/output device. Example 9 includes the apparatus of example 8, wherein the processor comprises one or more processor cores.

Example 10 includes the system of example 8, wherein the processor is to communicate with an external device via Hot Swap Back Plane (HSBP). Example 11 includes an apparatus comprising: a pin of an edge card to be protected by a seal to prevent a cooling liquid from making electrical contact with the pin of the edge card, wherein the edge card is to be inserted in a connector; and a terminal of the connector to be protected by an adhesive to prevent the cooling liquid to cause electrical contact with the terminal of the connector. Example 12 includes the apparatus of example 11, wherein the connector is to be coupled to a printed circuit board prior to application of the adhesive.

Example 13 includes the apparatus of example 11, wherein the seal comprises silicone gel. Example 14 includes the apparatus of example 11, wherein the adhesive comprises hot glue. Example 15 includes the apparatus of example 11, wherein the seal comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene. Example 16 includes the apparatus of example 11, wherein the adhesive comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene. Example 17 includes the apparatus of example 11, wherein the edge card comprises one or more of: a processor, a storage device, a communication device, or an input/output device.

Example 18 includes a system comprising: a processor to be provided on an edge card; a seal to prevent a cooling liquid from making electrical contact with a pin of the edge card to be inserted in a connector; and an adhesive to prevent the cooling liquid to cause electric contact with a terminal of the connector. Example 19 includes the system of example 18, wherein the connector is to be coupled to a printed circuit board prior to application of the adhesive. Example 20 includes the system of example 18, wherein the edge card further comprises one or more of: a storage device, a communication device, or an input/output device.

Example 21 includes an apparatus comprising means to perform a method as set forth in any preceding example. Example 22 includes a machine-readable storage including machine-readable instructions, when executed, to implement a method or realize an apparatus as set forth in any preceding example.

In various embodiments, the operations discussed herein, e.g., with reference to FIG. 1 et seq., may be implemented as hardware (e.g., logic circuitry or more generally circuitry or circuit), software, firmware, or combinations thereof, which may be provided as a computer program product, e.g., including a tangible (e.g., non-transitory) machine-readable or computer-readable medium having stored thereon instructions (or software procedures) used to program a computer to perform a process discussed herein. The machine-readable medium may include a storage device such as those discussed with respect to FIG. 1 et seq.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
a seal to prevent a cooling liquid from making electrical contact with a pin of an edge card to be inserted in a connector; and
an adhesive to prevent the cooling liquid to cause electrical contact with a terminal of the connector,
wherein the connector is to be coupled to a printed circuit board prior to application of the adhesive.

2. The apparatus of claim 1, wherein the connector is to be coupled to the printed circuit board via soldering.

3. The apparatus of claim 1, wherein the cooling liquid comprises a fluorochemical liquid, a polyalphaolefin liquid, mineral oil, or combinations thereof.

4. The apparatus of claim 1, wherein the seal comprises silicone gel.

5. The apparatus of claim 1, wherein the adhesive comprises hot glue.

6. The apparatus of claim 1, wherein the seal comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene.

7. The apparatus of claim 1, wherein the adhesive comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene.

8. The apparatus of claim 1, wherein the edge card comprises one or more of: a processor, a storage device, a communication device, or an input/output device.

9. The apparatus of claim 8, wherein the processor comprises one or more processor cores.

10. The system of claim 8, wherein the processor is to communicate with an external device via Hot Swap Back Plane (HSBP).

11. An apparatus comprising:
a pin of an edge card to be protected by a seal to prevent a cooling liquid from making electrical contact with the pin of the edge card, wherein the edge card is to be inserted in a connector; and
a terminal of the connector to be protected by an adhesive to prevent the cooling liquid to cause electrical contact with the terminal of the connector.

12. The apparatus of claim 11, wherein the connector is to be coupled to a printed circuit board prior to application of the adhesive.

13. The apparatus of claim 11, wherein the seal comprises silicone gel.

14. The apparatus of claim 11, wherein the adhesive comprises hot glue.

15. The apparatus of claim 11, wherein the seal comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene.

16. The apparatus of claim 11, wherein the adhesive comprises one or more of: silicone, hot glue, epoxy, polymer composite, glass solder, rubber, natural rubber, Styrene butadiene rubber, Butadine rubber, Isoprene rubber, Ethylene-Propylene-Diene-Monomer (EPDM), Butyl rubber, Nitrile rubber, Chloroprene rubber, Fluorocarbon elastomers, Plysulfide rubber, Polyurethanes, and Chlorosulfonated polyethylene.

17. The apparatus of claim 11, wherein the edge card comprises one or more of: a processor, a storage device, a communication device, or an input/output device.

18. A system comprising:
a processor to be provided on an edge card;
a seal to prevent a cooling liquid from making electrical contact with a pin of the edge card to be inserted in a connector; and
an adhesive to prevent the cooling liquid to cause electric contact with a terminal of the connector.

19. The system of claim 18, wherein the connector is to be coupled to a printed circuit board prior to application of the adhesive.

20. The system of claim 18, wherein the edge card further comprises one or more of: a storage device, a communication device, or an input/output device.
